(19) United States
(12) Patent Application Publication
(10) Pub. No.: US 2008/0191191 A1
(43) Pub. Date: Aug. 14, 2008

(54) Light Emitting Diode of a Nanorod Array Structure Having a Nitride-Based Multi Quantum Well

(75) Inventor: Hwa Mok Kim, Seoul (KR)

Correspondence Address: H.C. PARK & ASSOCIATES, PLC, 8500 LEESBURG PIKE, SUITE 7500, VIENNA, VA, 22182, US

(73) Assignee: SEOUL OPTO DEVICE CO., LTD., Ansan-si, Gyeonggi-do (KR)

(21) Appl. No.: 11/993,966

(22) PCT Filed: Jun. 27, 2005
(86) PCT No.: PCT/KR05/02004

§ 371 Date: Dec. 26, 2007

(51) Int. Cl. H01L 33/00

(52) U.S. Cl. 257/13; 438/34; 257/E33.008

(57) ABSTRACT

The present invention relates to a GaN light emitting diode. The GaN LED according to the present invention uses a GaN nanorod in which a multi quantum well formed by alternately stacking a plurality of InGaN layers and a plurality of GaN barriers is inserted into a p-n junction interface of a p-n junction GaN nanorod so that an n-type GaN nanorod, the multi quantum well, and a p-type GaN nanorod are sequentially arranged in a longitudinal direction. By arranging such GaN nanorods in an array, it is possible to provide an LED with higher luminance and higher light-emission efficiency as compared with a conventional laminated-film type GaN LED. It is possible to implement multi-color light with high luminance at a chip level by adjusting the amount of In and/or the thickness of the InGaN layers.

### TECHNICAL FIELD

The present invention relates to a light emitting diode (hereinafter, referred to as “LED”), and more particularly, to a light emitting diode with a nanorod (or, nanowire) structure and a method of fabricating the same.

### BACKGROUND ART

Initially, an LED has been widely used as a simple display element for an instrument panel. In recent years, the LED attracts attention as a full color display device with high luminance, high visibility and long life cycle, such as a large-sized electronic display board, and light sources for backlight and general illumination. This is achieved through recent development of blue and green LEDs with high luminance. Meanwhile, a III-nitrogen compound semiconductor such as GaN is recently studied as a material for LEDs. This is because a III-V group nitride semiconductor has wide bandgap and thus enables obtainment of light in a substantially full range of wavelength from visible light to an ultraviolet ray according to the composition of the nitride. However, since there is no substrate whose lattice matches with that of GaN, a sapphire substrate is mainly used. However, many problems still often occur due to the lattice mismatch and there is a large difference between their thermal expansion coefficients.

Therefore, a typical GaN LED, i.e., a laminated-film type LED formed by sequentially stacking an n-type impurity-doped n-GaN layer, an InGaN active layer, and a p-type impurity-doped p-GaN layer on a sapphire substrate, has limited performance (luminance), because there are a great deal of threading dislocations caused by lattice mismatching due to physical properties or limitations on growth of GaN. A laminated-film GaN LED has advantages in that it is relatively easy to design and fabricate and has low temperature sensitivity, while it has disadvantages of a low efficiency of light emitting, a wide spectrum width, a high output deviation and the like, as well as the threading dislocations.

To overcome the disadvantages of the laminated-film type LED, a nano-scaled LED with a p-n junction formed of one-dimensional rods or line-shaped nanorods (nanowires), or a micro-scaled LED such as a micro-ring or a micro-disc has been studied. Unfortunately, many threading dislocations also occur in such a nano-scaled or micro-scaled LED, similarly to a laminated-film type LED. Thus, an LED with a satisfactory level of high luminance has not yet appeared. Further, since the nanorod-structured LED is a simple p-n junction diode, it is difficult to obtain high luminance. The micro-ring or micro-disc LEDs are currently fabricated by means of photolithography. In a photolithography and etching process, however, the lattice structure of GaN is damaged. This makes the luminance or light-emission efficiency of a product unsatisfactory.

Meanwhile, a white LED is used as a light source for backlighting a display such as an LCD, or a light source for general illumination. Such a white LED can be implemented by an LED chip for emitting a blue or ultraviolet ray and a fluorescent material that absorbs light emitted from the LED chip and emits visible light. Generally, the fluorescent material is mixed into a transparent material such as epoxy for covering the LED chip. Accordingly, fabrication of such a white LED requires processes of preparing a transparent material with a fluorescent material uniformly distributed therein on the LED chip, and forming the transparent material on the LED chip. This complicates the process of fabricating the white LED, particularly, a packaging process.

### DISCLOSURE OF INVENTION

### Technical Problem

An object of the present invention is to provide an LED structure with high luminance and high light-emission efficiency.

Another object of the present invention is to provide an LED with high luminance and high light-emission efficiency, which can implement multi-color light at a chip level.

A further object of the present invention is to provide a method of fabricating an LED with high luminance and high light-emission efficiency, which can implement multi-color light at a chip level.

### Technical Solution

To achieve the objects of the present invention, an LED of the present invention uses a nanorod in which a multi quantum well formed by alternately stacking a plurality of (AlₓIn_{y}Ga_{1-x-y})N (where, 0≦x<1, 0≦y≦1 and 0≦x+y≦1) layers and a plurality of (AlₓIn_{y}Ga_{1-x-y})N (where, 0≦x≦1, 0≦y<1 and 0≦x+y≦1) barriers is inserted into a p-n junction interface of a p-n junction nanorod so that an n-type nanorod, the multi quantum well, and a p-type nanorod are sequentially arranged in a longitudinal direction. By arranging such GaN nanorods in an array, there is provided an LED with higher luminance and higher light-emission efficiency as compared with a conventional laminated-film type GaN LED.

That is, a light emitting diode of the present invention comprises a substrate; a nanorod array including a plurality of nanorods each of which includes a first conductive nanorod formed perpendicularly to the substrate, a multi quantum well formed by alternately stacking a plurality of (AlₓIn_{y}Ga_{1-x-y})N (where, 0≦x<1, 0≦y≦1 and 0≦x+y≦1) layers, and a plurality of (AlₓIn_{y}Ga_{1-x-y})N (where, 0≦x≦1, 0≦y<1 and 0≦x+y≦1) barriers on the first conductive nanorod, and a second conductive nanorod formed on the multi quantum well; an electrode pad connected in common to the first conductive nanorods of the nanorod array for applying a voltage thereto; and a transparent electrode connected in common to the second conductive nanorods of the nanorod array for applying a voltage thereto. In this case, the first and second conductive nanorods refer to n- and p-types, respectively. Alternatively, the first and second conductive nanorods refer to p- and n-types, respectively.

The first and second nanorods are formed of a semiconductor material that well matches the (AlₓIn_{y}Ga_{1-x-y})N quantum well in view of their lattices. For example, the nanorods may be GaN or ZnO based nanorods. The GaN based nanorod may be formed of GaN or a ternary or quaternary nitride containing Al and/or In added to GaN and may be represented by a general formula, AlₓIn_{y}Ga_{(1-x-y)}N (where, 0≦x≦1, 0≦y<1 and 0≦x+y≦1). The ZnO based nanorod may be formed of ZnO or a ternary oxide containing Mg added to ZnO and may be represented by a general formula, Zn₁₋ₓMgₓO (where, 0≦x<1).

At least two of the plurality of (AlₓIn_{y}Ga_{1-x-y})N layers may be formed to have different amounts of In or different thicknesses to emit light with at least two peak wavelengths.

Meanwhile, a transparent insulating material such as spin-on-glass (SOG), SiO₂, epoxy or silicone may be filled in spaces between the plurality of nanorods. Further, the transparent insulating material may further comprise a fluorescent material for converting a portion of light emitted from the nanorods into light with a longer wavelength.

According to the present invention, it is possible to provide an LED with high luminance and high light-emission efficiency by employing a nanorod array with nitride multi quantum wells inserted therein. It is possible to provide a light emitting diode capable of implementing multi-color light such as white light at a chip level by adjusting the amounts of In in the (AlₓIn_{y}Ga_{1-x-y})N layers or the thicknesses of the (AlₓIn_{y}Ga_{1-x-y})N layers, or by incorporating a fluorescent material into the transparent material for filling the spaces between the nanorods.

Meanwhile, a method of fabricating a light emitting diode according to the present invention comprises the step of forming a plurality of first conductive nanorods perpendicular to a substrate in an array. A multi quantum well formed by alternately stacking a plurality of (AlₓIn_{y}Ga_{1-x-y})N (where, 0≦x<1, 0≦y≦1 and 0≦x+y≦1) layers at least two of which have different amounts of In, and a plurality of (AlₓIn_{y}Ga_{1-x-y})N (where, 0≦x≦1, 0≦y<1 and 0≦x+y≦1) barriers is formed on each of the plurality of the first conductive nanorods. Then, a second conductive nanorod is formed on each of the multi quantum wells. Further, an electrode pad for applying a voltage to the first conductive nanorods, and a transparent electrode connected in common to the second conductive nanorods for applying a voltage thereto are formed. Here, the first conductive nanorod, the multi quantum well and the second conductive nanorod may be formed in-situ by means of metalorganic-hydride vapor phase epitaxy (MO-HVPE), molecular beam epitaxy (MBE) or metalorganic chemical vapor deposition (MOCVD). At least two of the plurality of (AlₓIn_{y}Ga_{1-x-y})N layers are formed to have different amounts of In or different thicknesses to emit light with at least two peak wavelengths.

With the LED and the method of fabricating the same according to the present invention, it is possible to obtain an LED with high luminance and high light-emission efficiency at a higher yield without the use of a catalyst or template.

### BRIEF DESCRIPTION OF THE DRAWINGS

FIG. 1 is a sectional view of a light emitting diode according to an embodiment of the present invention.

FIG. 2 is a plan view of the light emitting diode shown in FIG. 1.

FIG. 3 is a sectional view showing the structure of a multi quantum well of the light emitting diode shown in FIG. 1.

FIGS. 4 to 7 are sectional views illustrating a process of fabricating a light emitting diode according to an embodiment of the present invention.

FIG. 8 is a scanning electron microscope (SEM) photograph of a nanorod array fabricated according to an embodiment of the present invention.

FIG. 9 is a graph showing EL intensity at the wavelength of emitted light with respect to a current in a light emitting diode fabricated according to an embodiment of the present invention.

FIG. 10 is a graph showing a peak wavelength at the current in the graph of FIG. 9.

FIG. 11 is a graph showing I-V characteristics of a light emitting diode fabricated according to an embodiment of the present invention and a conventional light emitting diode.

FIG. 12 is a graph showing light output-to-forward current characteristics of the light emitting diode fabricated according to the embodiment of the present invention and the conventional light emitting diode.

FIG. 13 is a schematic view showing one nanorod with electrodes formed thereon.

FIG. 14 is a graph showing an I-V characteristic in the case of FIG. 13.

### BEST MODE FOR CARRYING OUT THE INVENTION

Hereinafter, preferred embodiments of the present invention will be described in detail with reference to the accompanying drawings. The following embodiments are provided only for illustrative purposes so that those skilled in the art can fully understand the spirit of the present invention. Therefore, the present invention is not limited to the following embodiments but may be implemented in other forms. In the drawings, the widths, lengths, thicknesses and the like of elements are exaggerated for convenience of illustration. Like reference numerals indicate like elements throughout the specification and drawings.

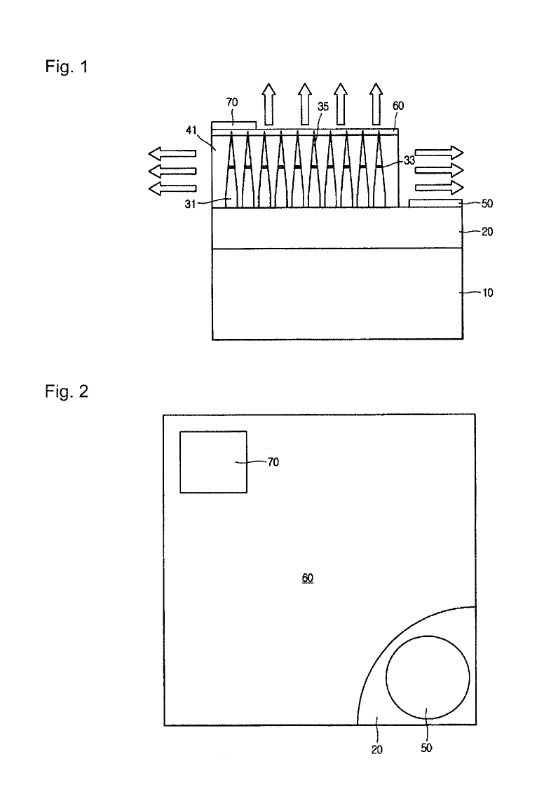

FIG. 1 is a sectional view of a light emitting diode (LED) according to an embodiment of the present invention, and FIG. 2 is a plan view of the LED shown in FIG. 1.

Referring to FIGS. 1 and 2, the LED of the embodiment comprises an n-type GaN buffer layer 20, a plurality of GaN nanorods 31, 33 and 35 arranged in an array, a transparent insulating material layer 41 for filling gaps among the GaN nanorods, a transparent electrode 60, and electrode pads 50 and 70, which are formed on a sapphire substrate 10.

The n-type GaN buffer layer 20 formed on the substrate 10 buffers mismatch of lattice constants between the substrate 10 and the n-type GaN nanorods 31 and enables a voltage to be supplied in common to the n-type GaN nanorods 31 via the electrode pad 50.

Each of the plurality of GaN nanorods 31, 33 and 35 arranged in the array on the n-type GaN buffer layer 20 comprises an n-type GaN nanorod 31, an InGaN quantum well 33, and a p-type GaN nanorod 35. The GaN nanorods are formed perpendicularly to the n-type GaN buffer layer 20 to have a substantially uniform height and diameter.

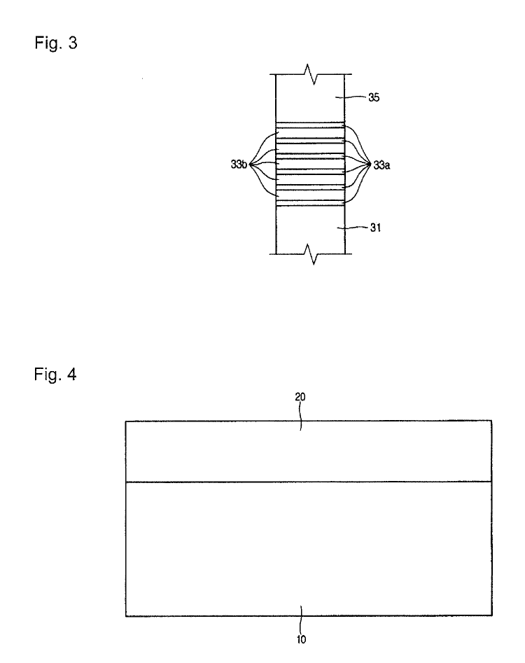

Here, the InGaN quantum well 33 is an active layer that enables visible light with higher luminance to be obtained as compared with a simple p-n junction diode without a quantum well. In this embodiment, as shown in FIG. 3, the quantum well has the structure of a multi quantum well that is formed by alternately stacking a plurality of InGaN layers 33a and a plurality of GaN barrier layers 33b. In particular, as will be described later, an interface between the InGaN layer 33a and the GaN barrier layer 33b of the multi quantum well 33 in the embodiment is very clear and has little dislocation.

The transparent insulating material layer 41 fills the gaps among the plurality of GaN nanorods 31, 33 and 35 to insulate the nanorods from one another and to protect the nanorods against possible shock. The transparent insulating material layer 41 servers as an underlayer that enables the transparent electrode 60 to be connected in common to the respective nanorods. The material of the transparent insulating material layer 41 includes, but not limited to, SOG, SiO₂, epoxy or silicone that is capable of sufficiently filling the gaps among the nanorods and being easily formed and that is transparent not to preclude light emitting through sidewalls of the nanorods (see, left and right arrows in FIG. 1). Further, the transparent insulating material layer 41 is formed to have such a height that it reaches slightly below the level of the p-type GaN nanorod 35. Thus, tips of the p-type GaN nanorods are connected in common to the transparent electrode 60.

The transparent electrode 60 is in ohmic contact with the p-type GaN nanorods 35 in common so as to apply a voltage thereto, and is formed of a transparent conductive material not to preclude light emitting in a longitudinal direction of the nanorods (upward in FIG. 1). The transparent electrode 60 may be, but not limited to, a thin film of Ni/Au.

The electrode pad 70 as a terminal for use in supplying a voltage to the transparent electrode (and thence the p-type GaN nanorods) is formed in a predetermined area on the transparent electrode 60. The electrode pad 70 may be formed of, but not limited to, a Ni/Au layer to which a wire (not shown) is to be bonded. Further, the electrode pad 50 for use in applying a voltage to the n-type GaN nanorods through the n-type GaN buffer layer 20 is formed on and is in ohmic contact with the n-type GaN buffer layer 20. This electrode pad 50 is formed of, but not limited to, a Ti/Al layer to which a wire (not shown) is to be bonded.

If a DC voltage is applied to the two electrode pads 50 and 70 of the LED of the embodiment constructed as above (in which a positive voltage is applied to the electrode pad 70 and a negative voltage or ground potential is applied to the electrode pad 50), light with high luminance is emitted through the side and upward directions of the nanorods each of which may be considered as a nano LED, as shown in FIG. 1.

Since the InGaN quantum well is particularly formed in each of the nanorods in this embodiment, visible light with higher luminance is emitted as compared to a simple p-n junction diode. Further, the plurality of nano LEDs lead to a remarkable increase in the area of light emitting (light emitting through the sidewall), thereby resulting in much higher emission efficiency as compared to a conventional laminated-film type LED.

Meanwhile, in this embodiment, the wavelength of the light emitted from the LEDs may be variously changed and white light may be obtained by adjusting the amount of In in the InGaN layers of the multi quantum well or the thickness of each of the InGaN layers. This will be described below in greater detail with reference to FIG. 3.

First, the amounts of In in the InGaN layers 33a are adjusted so that the InGaN layers have different amounts of In. As the amount of In increases, the InGaN layer has a narrower bandgap, resulting in a longer wavelength of emitted light. Accordingly, the InGaN layers having different amounts of In emit light with different peak wavelengths. The greater amount of In allows light to be emitted with a longer wavelength. As a result, it is possible to form an InGaN layer with a desired peak wavelength ranging from an ultraviolet ray region of 370 nm to an infrared ray region by adjusting the amount of In, thereby enabling all visible light including blue, green, and red light to be obtained.

It is possible to fabricate a light emitting diode capable of implementing white light at a chip level by adjusting the amounts of In in the InGaN layers 33a so that the InGaN layers 33a have peak wavelengths in blue and yellow regions, or blue, green and red regions. In addition to the peak wavelengths in these color regions, it is possible to significantly improve a color rendering index of a white light emitting diode by adjusting the amounts of In in the InGaN layers 33a so that the InGaN layers 33a can also have peak wavelengths in other color regions.

Meanwhile, the wavelength of emitted light can be changed by adjusting the thickness of the InGaN layer 33a. That is, if the thickness of the InGaN layer is reduced to be less than a Bohr excitation radius, the bandgap of the InGaN layer increases. Thus, by adjusting the thicknesses of the InGaN layers 33a, it is possible to form a multi-layer quantum well that emits light with at least two peak wavelengths. Accordingly, multi-color light including white light can be implemented.

The amounts of In and the thicknesses of the InGaN layers may be simultaneously adjusted so that InGaN layers 33a emit light with different peak wavelengths.

Further, multi-color light may also be obtained by using a fluorescent material. In particular, in this embodiment, a white light emitting diode can be simply fabricated by adding a fluorescent material to the transparent insulating material 41 to obtain white light. For example, white light may be emitted by forming the quantum well so that the nanorods 30 emit blue light and by adding a yellow fluorescent material to the transparent insulating material 41.

Although the LED structure of the embodiment has been described, various modifications may be made to the specific structure and material thereof. For example, although the n-type GaN layer is formed and the p-type GaN nanorod is formed thereon, they may be formed in a reverse order. Further, the InGaN layers may be made of a nitride represented by a general formula (AlₓIn_{y}Ga_{1-x-y})N (where, 0≦x<1, 0≦y≦1 and 0≦x+y≦1), and the n-type and p-type GaN nanorods may be made of either nitride nanorods represented by a general formula AlₓIn_{y}Ga_{(1-x-y)}N (where, 0≦x≦1, 0≦y<1 and 0≦x+y≦1) or ZnO. Further, the GaN barrier is made of a nitride represented by a general formula AlₓIn_{y}Ga_{(1-x-y)}N (where, 0≦x≦1, 0≦y<1 and 0≦x+y≦1) and may contain a smaller amount of In as compared with an adjacent InGaN layer. Further, the positions or shapes of the electrode pads 50 and 70 are not limited to those shown in FIGS. 1 and 2 but may take other positions or shapes so long as they can apply a voltage to the n-type GaN nanorods 31 and the p-type GaN nanorods 35 in common.

While sapphire has been used for the substrate 10 above, a glass substrate, a SiC substrate, a ZnO substrate or a silicon substrate may be used. In this case, the silicon may become a conductor through doping of suitable impurities (n-type impurities in the above embodiment), unlike the sapphire or glass substrate that are insulating materials. This allows omission of the n-type GaN buffer layer 20, and the electrode pad 50 may be formed on a bottom surface of the silicon substrate (opposing to a surface of the substrate on which the nanorods 30 are formed) rather than on a portion on a top surface of the n-type GaN buffer layer 20. Since the ZnO substrate and the SiC substrate generally have conductivity, the n-type GaN buffer layer 20 may be omitted and the electrode pad 50 may be formed on the bottom surface of the substrate, in the same manner as the silicon substrate.

A method of fabricating the LED of the embodiment will be described below.

First, a method of growing GaN using an epitaxial growth method will be described. The method of growing an epitaxial layer includes a vapor phase epitaxial (VPE) growth method, a liquid phase epitaxial (LPE) growth method, and a solid phase epitaxial (SPE) growth method. In the VPE growth method, a crystal is grown on a substrate through thermal decomposition and reaction of a reaction gas supplied onto the substrate. The VPE growth method can be classified into hydride VPE (HVPE), halide VPE, metalorganic VPE (MOVPE) and the like according to the type of raw material of the reaction gas.

While the GaN layer and the InGaN/GaN quantum well are described in this embodiment as being formed using the metalorganic hydride VPE (MO-HVPE) growth, the present invention is not necessarily limited thereto. The GaN layer and the InGaN/GaN quantum well may be formed by using another suitable growth method, e.g., molecular beam epitaxy (MBE) or metalorganic chemical vapor deposition (MOCVD).

GaCl, trimethylindium and NH₃ are used as precursors of Ga, In and N, respectively. GaCl may be obtained by reacting metal gallium and HCl with each other at a temperature of 600 to 950° C. Further, impurity elements doped for growth of n-type GaN and p-type GaN are Si and Mg, respectively, and are supplied in the form of SiH₄ and Bis(cyclopentadienyl)magnesium (Cp₂Mg), respectively.

Now, a method of fabricating the LED according to the embodiment will be described in detail with reference to FIGS. 4 to 7.

As shown in FIG. 4, a sapphire substrate 10 is first placed in a reactor (not shown) and an n-type GaN buffer layer 20 is then formed on the substrate 10. While the n-type GaN buffer layer 20 may be formed by doping Si as described above, an n-type GaN buffer layer 20 may be formed to have a thickness of about 1.5 μm without artificial doping by supplying precursors of Ga and N at flow rates of 30 to 70 sccm and 1000 to 2000 sccm for 50 to 60 minutes at a temperature of 400 to 500° C. under the atmospheric pressure or a slight positive pressure, based on the fact that GaN grown without artificial doping has n-type properties due to the presence of nitrogen vacancy, oxygen impurities or the like.

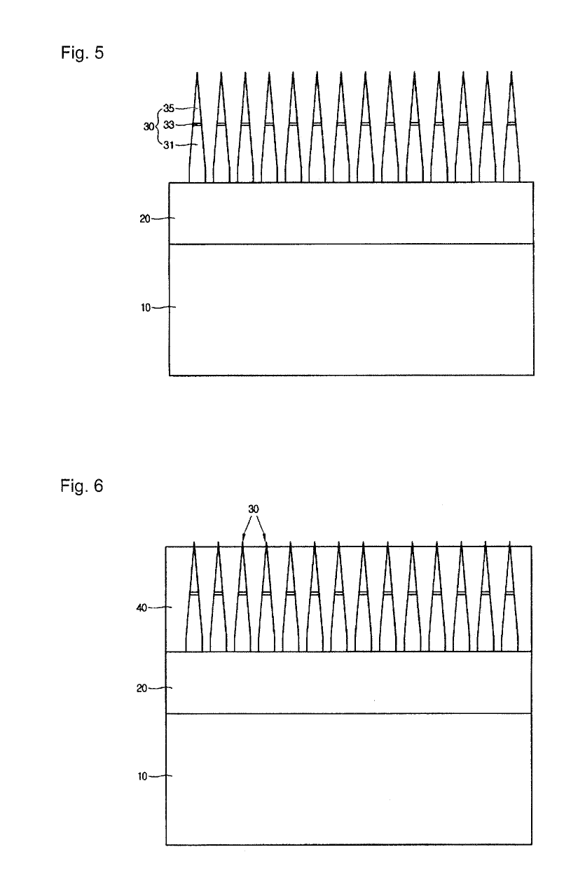

Then, an array of a plurality of nanorods 30 is formed as shown in FIG. 5. Preferably, the formation of the array is continuously carried out in-situ within the reactor in which the n-type GaN buffer layer 20 has been grown. Specifically, n-type GaN nanorods 31 are first grown. That is, the n-type GaN nanorods 31 can be formed to have a height of about 0.5 μm perpendicularly to the n-type GaN buffer layer 20 by supplying precursors of Ga and N to the reactor at respective flow rates of 30 to 70 sccm and 1000 to 2000 sccm and simultaneously supplying SiH₄ in a flow rate of 5 to 20 sccm for 20 to 40 minutes at a temperature of 400 to 600° C. under the atmospheric pressure or a slight positive pressure.

Meanwhile, if GaN is grown at a high temperature (e.g., 1000° C. or more), an initial GaN seed is rapidly grown upwardly and laterally in the form of a thin film rather than a nanorod. In this case, dislocations inevitably occurs at the boundaries where seeds meet one another due to lateral growth thereof and the dislocations propagate in a thickness direction when the thin film is grown in the thickness direction, resulting in threading dislocations. However, by maintaining the process conditions as in the above embodiment, the seeds are grown upwardly without the use of an additional catalyst or template, resulting in the growth of a plurality of n-type GaN nanorods 31 with a substantially uniform height and diameter.

InGaN quantum wells 33 are then grown on the n-type GaN nanorods 31. Preferably, this process is also continuously carried out in-situ within the reactor in which the n-type GaN nanorods 31 have been grown. Specifically, precursors of Ga, In and N are supplied into the reactor at respective flow rates of 30 to 70 sccm, 10 to 40 sccm and 1000 to 2000 sccm at a temperature of 400 to 500° C. under the atmospheric pressure or a slight positive pressure. Thus, the InGaN quantum wells 33 are formed on the n-type GaN nanorods 31. At this time, growth time of the InGaN quantum wells 33 is properly selected until the InGaN quantum wells 33 are grown to have a desired thickness. Because the thickness of the quantum wells 33 is a factor determining the wavelength of light emitted from a completed LED as described above, the growth time is determined according to the thickness of the quantum wells 33 set for light with a desired wavelength. Further, because the wavelength of the emitted light varies with the amount of In, the ratio of supplied precursors is adjusted according to a desired wavelength so as to adjust the amount of in.

The InGaN quantum wells 33 are formed to have a multi quantum well structure obtained by alternately stacking a plurality of InGaN layers 33a and a plurality of GaN barrier layers 33b, as shown in FIG. 3. This can be obtained by repeatedly interrupting the supply of the precursor of In for a predetermined period of time.

Subsequently, p-type GaN nanorods 35 are grown on the InGaN quantum wells 33. Preferably, this process is continuously carried out in-situ in the reactor in which the InGaN quantum wells 33 have been grown. Specifically, the p-type GaN nanorods 35 may be formed to have a height of about 0.4 μm perpendicularly to the substrate 10 by supplying precursors of Ga and N into the reactor at respective flow rates of 30 to 70 sccm and 1000 to 2000 sccm and simultaneously supplying Cp₂Mg at a flow rate of 5 to 20 sccm for 20 to 40 minutes at a temperature of 400 to 600° C. under the atmospheric pressure or a slight positive pressure.

FIG. 8 is a scanning electron microscope (SEM) photograph of an array of the nanorods 30 grown as described above. As can be seen from FIG. 8, the nanorods 30 including the InGaN quantum wells grown by the method of the embodiment have a substantially uniform height and diameter and are grown at a significantly high density. The nanorods 30 grown under the aforementioned process conditions have an average diameter of about 70 to 90 nm around the quantum wells 33. The nanorods 30 have an average gap of about 100 nm between adjacent nanorods.

After the array of the nanorods 30 is thus formed, the gap between the adjacent nanorods 30 is filled with a transparent insulating material layer 40, as shown in FIG. 6. The transparent insulating material may be SOG, SiO₂, epoxy or silicone, as described above. In case of the use of SOG, spin coating and curing processes results in the structure shown in FIG. 6. Upon filling the gaps with SOG, the gap between the adjacent nanorods 30 is preferably 80 nm or more so that the gap can be fully filled therewith. Meanwhile, the transparent insulating material layer 40 has a thickness to be slightly below the level of the height of the nanorods 30.

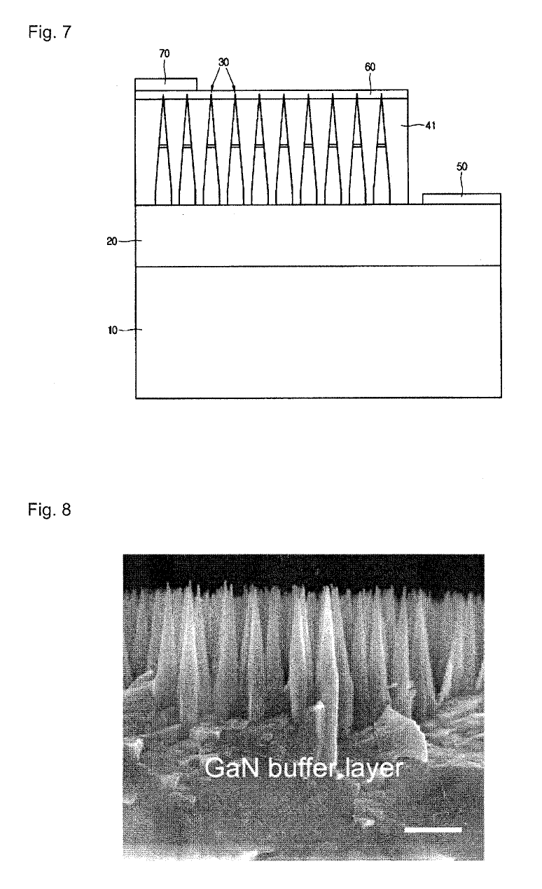

Electrode pads 50 and 70 and a transparent electrode 60 for applying a voltage are then formed, as shown in FIG. 7, thereby completing a GaN LED with the nanorod array structure including the InGaN quantum wells. Specifically, in order to form the electrode pad 50 for applying a voltage to the n-type GaN nanorods 31, the transparent insulating material layer 40 and the nanorods 30 are first partially removed in the state of FIG. 6 so that a portion of the n-type GaN buffer layer 20 is exposed. Then, the electrode pad 50 is formed on the exposed portion of the buffer layer 20 through a lift-off process. This electrode pad 50 may be formed into a Ti/Al layer by means of electron-beam evaporation. Similarly, the transparent electrode 60 and the electrode pad 70 are formed into, for example, Ni/Au layers.

Meanwhile, the transparent electrode 60 comes in natural contact with the nanorods 30, which slightly protrude beyond the transparent insulating material layer 41, and is electrically connected to the p-type GaN nanorods 35. Preferably, the transparent electrode 60 has a small thickness enough not to preclude light emitted from the individual nano LEDs. Preferably, the two electrode pads 50 and 70 have thicknesses sufficient to allow external connection terminals, such as wires, to be connected to the pads by means of bonding or the like.

With the method of fabricating the GaN LED according to this embodiment, it is possible to uniformly grow the array of nanorods each of which sequentially includes the n-type GaN nanorod 31, the InGaN quantum well 33 and the p-type GaN nanorod 35 without the use of a special catalyst or template.

Meanwhile, less critical features in the embodiment may be freely changed. For example, the sequence and the method of forming the electrode pads 50 and 70 and the transparent electrode 60 may be changed into several known methods (deposition, photolithography and etching, etc.). Further, a precursor of Al, such as trimethylaluminum (TMA), may be supplied while the quantum well 33 and the nanorods 31 and 35 are being formed, resulting in the quantum wells and nanorods of AlₓIn_{y}Ga_{(1-x-y)}N. In particular, other known equivalent materials may substitute for the respective materials in the aforementioned embodiment, and the process conditions may deviate from the aforementioned range depending on a reactor or materials to be used.

While the sapphire substrate has been used as the substrate 10, a glass substrate, a SiC substrate, a ZnO substrate or a silicon substrate (preferably, a silicon substrate doped with an n-type impurity, such as P) may be used. Since the method of fabricating the nanorods according to the embodiment is performed at a low temperature, it is possible to use a glass substrate. Further, when a SiC, ZnO or silicon substrate is used, the process of forming the n-type GaN buffer layer 20 may be omitted and the electrode pad 50 may be formed on a bottom surface of the substrate rather than on a portion of the GaN buffer layer 20. That is, the electrode pad may be first formed on one surface of the substrate and the nanorods 30 may be formed directly on the other surface opposite thereto.

The GaN LED of the embodiment was fabricated in the following way and light-emitting properties thereof were examined, which will be briefly described. Specific numerals and processes proposed in the following description are only illustrative and the present invention is not limited thereto.

First, a sapphire (0001) wafer was prepared as the substrate 10, and the n-type GaN buffer layer 20 and the GaN nanorods 30 were grown in-situ by means of the aforementioned MO-HVPE method using the aforementioned precursors. The InGaN quantum wells 33 of the nanorods 30 had such a composition ratio that InₓGa₁₋ₓN became In_{0.25}Ga_{0.75}N, so that a completed LED emitted light with a wavelength of 470 nm or less. Further, InGaN/GaN repeated with six periods was used as the multi quantum well. Detailed process conditions and the results are shown in Table 1 below:

TABLE 1

| | n-type GaN | n-type GaN | | GaN | p-type GaN |
|---|---|---|---|---|---|
| | buffer layer | nanorod | InGaN layer | Barrier | nanorod |
| | (20) | (31) | (33a) | (33b) | (35) |
| Substrate temperature | 550° C. | 460° C. | 460° C. | 460° C. | 460° C. |
| Pressure | about 1 atm | about 1 atm | about 1 atm | about 1 atm | about 1 atm |
| Growth time | 50 minutes | 20 minutes | 10 seconds | 25 seconds | 20 minutes |
| Flow rate of precursor | Ga: 50 | Ga: 50 | Ga: 50 | Ga: 50 | Ga: 50 |
| or dopant gas (sccm) | N: 2000 | N: 2000 | N: 2000 | N: 2000 | N: 2000 |
| | | Si: 5 | In: 10 | | Mg: 10 |
| Thickness (height) | 1.5 μm | 0.5 μm | 4.8 nm | 12 nm | 0.5 μm |

With these process conditions, an array of nanorods with multi quantum wells, which occupies an area of 33 mm², was obtained. This nanorod array included about 8×10⁷ nanorods 30 in an area of 1 mm². The nanorods 30 had an average diameter of about 70 nm around a quantum well layer thereof and a height of about 1 μm. The n- and p-type GaN nanorods 31 and 35 had carrier concentrations of about 1×10¹⁸ cm⁻³ and about 5×10¹⁷ cm⁻³, respectively. The InGaN quantum well had a composition ratio of In_{0.25}Ga_{0.75}N.

The nanorods 30 with a high aspect ratio were then spin-coated with SOG (under the tradename ACCUGLASS T-12B available from Honeywell Electronic Materials) at a rotational speed of 3000 rpm for 30 seconds, and annealed and cured at a temperature of 260° C. for 90 seconds within an air atmosphere so that gaps between the nanorods 30 were uniformly filled with the SOG without voids. In the embodiment, such spin coating and curing processes were carried out two times so that the gaps were sufficiently filled with the SOG. Thereafter, a transparent insulating material layer 40 was formed to have a thickness of about 0.8 to 0.9 μm through annealing for 20 minutes at a temperature of 440° C. in a furnace with a nitrogen atmosphere.

With a lift-off process and an electron-beam evaporation process, a Ti/Al electrode pad 50 with a thickness of 20/200 nm was formed on the n-type GaN buffer layer 20 which is partially exposed using photolithography and dry etching processes, and a Ni/Au transparent electrode 60 was deposited to have a thickness of 20/40 nm to be in ohmic contact with the respective nano-scaled LEDs 30. Similarly to the electrode pad 50, a Ni/Au electrode pad 70 was finally formed to have a thickness of 20/200 mm.

As a comparative example, a laminated-film type GaN LED with the same size was fabricated. In the LED of the comparative example, the thickness and the construction of each layer were the same as those of the embodiment of the present invention but the comparative example was different from the embodiment of the present invention only in that it did not have nanorods.

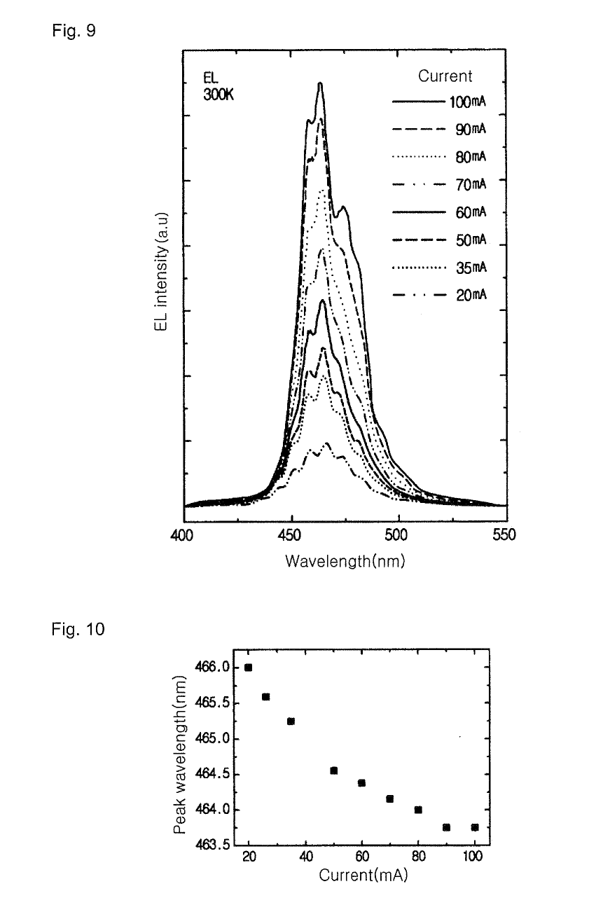

FIG. 9 is a graph showing an electroluminescence (EL) spectrum when a DC current of 20 to 100 mA is applied to the LED of the embodiment fabricated as above. It can be seen from FIG. 9 that the LED of the embodiment is a blue LED with a wavelength of about 465 nm. Further, as can be seen from FIG. 10, the LED of the embodiment exhibits a blue-shift phenomenon in which the peak wavelength become shorter as the supply current increases. It is believed that the phenomenon is caused by a screen effect of a built-in internal polarization field within a quantum well due to injected carriers.

FIG. 11 is a graph showing an I-V characteristic of the LED of the embodiment and the LED of the comparative example at room temperature. As can be seen from FIG. 11, the LED of the embodiment has a turn-on voltage slightly higher than that of the comparative example. This may be because the LED of the embodiment had an effective contact area much smaller than that of the comparative example (the LED of the embodiment may be considered as a collection of a plurality of nano LEDs and a contact area of each nano LED with the electrode 60 is much smaller than that in the comparative example), and thus, the former had relatively greater resistance.

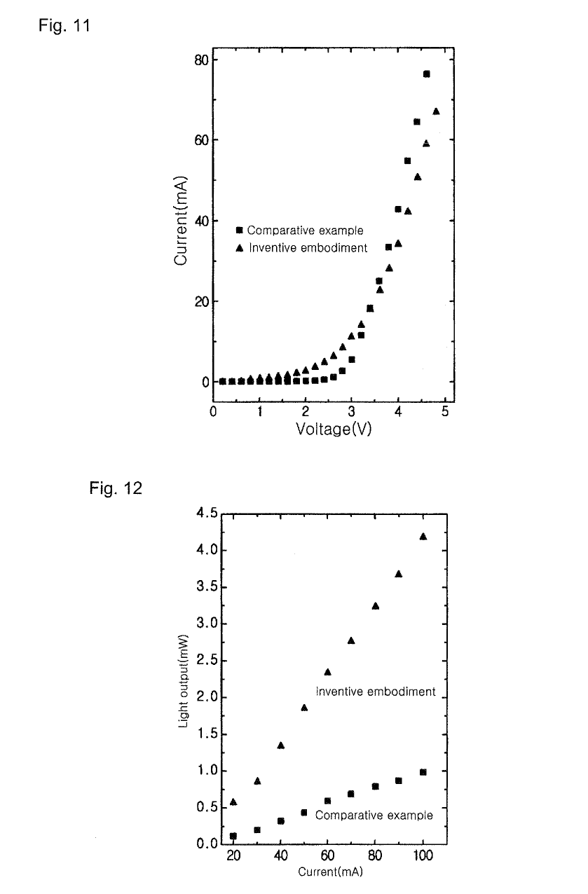

FIG. 12 is a graph showing light output vs. a forward current, wherein it can be seen that the LED of the embodiment has much greater light output as compared with that of the comparative example (e.g., the LED of the embodiment has light output greater 4.3 times at a current of 20 mA when a detected area of an optical detector is 1 mm², and an actual difference in light output may be greater than the aforementioned numeral). This is because light emitted through sidewalls can be effectively used by forming the nanorod array as described above, contrary to a laminated-film type LED with the same area. From a temperature-dependent photoluminescence (PL) experiment, it could also be found that the LED of the embodiment has much excellent quantum efficiency.

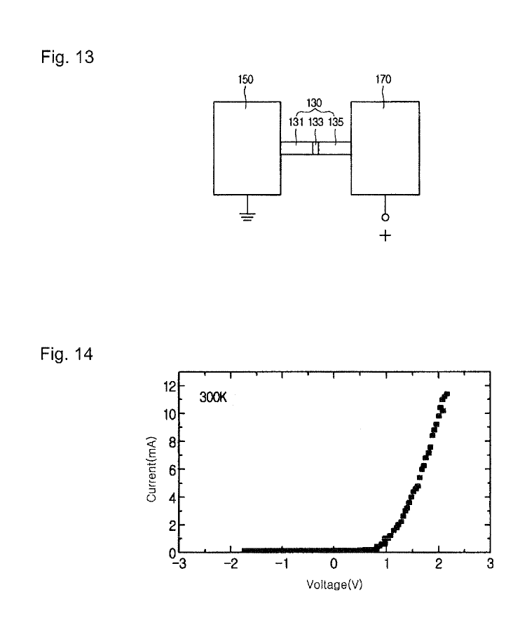

FIG. 13 is a view showing one InGaN quantum well nanorod with electrodes formed thereon, and FIG. 14 is a graph showing an I-V characteristic in the case of FIG. 13. The nano LED with the structure shown in FIG. 13 can be obtained by dispersing the nanorod array fabricated as above in methanol and then attaching it to a substrate such as an oxidized silicon substrate, and by forming a Ti/Al electrode pad 150 on the side of an n-type GaN nanorod 131 and an Ni/Au electrode pad 170 on the side of a p-type GaN nanorod 135. An I-V characteristic of a nano LED comprising one nanorod thus obtained was examined and the results are shown in FIG. 14. As can be seen FIG. 14, this nano LED exhibits a very clear and exact rectification characteristic. It is considered that this may be because the p- and n-type nanorods and the quantum well were grown by means of single epitaxial growth.

Although the present invention has been described in connection with the specific embodiments and the drawings, it is not limited thereto. It will be apparent to those skilled in the art that various modifications and changes can be made thereto within the technical spirit and scope of the present invention defined by the appended claims.

### INDUSTRIAL APPLICABILITY

According to the present invention, it is possible to obtain a diode with high luminance and high quality by forming an array of nanorods with AlₓIn_{y}Ga_{(1-x-y)}N multi quantum wells by means of single epitaxial growth. In particular, it is possible to obtain an LED with high luminance by forming an array of nanorods with AlₓIn_{y}Ga_{(1-x-y)}N quantum wells, thereby allowing effectiveness of light emitting through sidewalls and significantly increasing light-emission efficiency as compared to a conventional LED with the same area. It is also possible to easily obtain an LED capable of outputting visible light or white light with a variety of wavelengths at a chip level according to the thickness of the AlₓIn_{y}Ga_{(1-x-y)}N quantum well, the amount of In and the use of a fluorescent material.

1. A light emitting diode, comprising:
a substrate;
a nanorod array including a plurality of nanorods, each of the nanorods including a first conductive nanorod formed perpendicularly to the substrate, a multi quantum well formed by alternately stacking a plurality of (AlₓIn_{y}Ga_{1-x-y})N (where, 0≦x<1, 0≦y≦1 and 0≦x+y≦1) layers at least two of which have different amounts of in, and a plurality of (AlₓIn_{y}Ga_{1-x-y})N (where, 0≦x≦1, 0≦y<1 and 0≦x+y≦1) barriers on the first conductive nanorod, and a second conductive nanorod formed on the multi quantum well;
an electrode pad connected in common to the first conductive nanorods of the nanorod array for applying a voltage thereto; and
a transparent electrode connected in common to the second conductive nanorods of the nanorod array for applying a voltage thereto.

2. The light emitting diode as claimed in claim 1, wherein each of the first conductive nanorod and the second conductive nanorod is formed of AlₓIn_{y}Ga_{(1-x-y)}N (where, 0≦x≦1, 0≦y<1 and 0≦x+y≦1) or ZnO.

3. The light emitting diode as claimed in claim 1, further comprising a transparent insulating material which fills spaces between the nanorods.

4. The light emitting diode as claimed in claim 3, wherein the transparent insulating material is spin-on-glass (SOG), SiO₂, epoxy or silicone.

5. The light emitting diode as claimed in claim 3, wherein the transparent insulating material fills the spaces between the nanorods to be at a level lower than the height of the nanorods so that tips of the nanorods slightly protrude.

6. The light emitting diode as claimed in claim 5, further comprising a fluorescent material for converting a portion of light emitted from the nanorods into light with a longer wavelength, wherein the fluorescent material is dispersed into the transparent insulating material, and light emitted from the light emitting diode becomes white light as a whole through mixing of the emitted light from the nanorods with the converted light.

7. The light emitting diode as claimed in claim 1, wherein each of the plurality of (AlₓIn_{y}Ga_{1-x-y})N layers has the amount of In adjusted such that light emitted from the light emitting diode becomes white light as a whole.

8. The light emitting diode as claimed in claim 7, wherein the white light has peak wavelengths within wavelength ranges of at least three colors.

9. The light emitting diode as claimed in claim 1, wherein the substrate is an insulating sapphire or glass substrate, a first conductive GaN buffer layer is interposed between the insulating substrate and the nanorods, and the electrode pad is formed on a portion of the GaN buffer layer.

10. The light emitting diode as claimed in claim 1, wherein the substrate is a conductive substrate of a material selected from the group consisting of silicon, SiC and ZnO, and the electrode pad is formed on one surface of the conductive substrate opposite to a surface thereof on which the nanorods are formed.

11. A method of fabricating a light emitting diode, comprising the steps of:
forming first conductive nanorods in an array perpendicularly to a substrate;
forming a multi quantum well by alternately stacking a plurality of (AlₓIn_{y}Ga_{1-x-y})N (where, 0≦x<1, 0≦y≦1 and 0≦x+y≦1) layers at least two of which have different amounts of In, and a plurality of (AlₓIn_{y}Ga_{1-x-y})N (where, 0≦x≦1, 0≦y<1 and 0≦x+y≦1) barriers on each of the first conductive nanorods;
forming a second conductive nanorod on each of the multi quantum wells;
forming an electrode pad for applying a voltage to the first conductive nanorods; and
forming a transparent electrode connected in common to the second conductive nanorods for applying a voltage thereto.

12. The method as claimed in claim 11, further comprising the step of filling a transparent insulating material in the spaces between the nanorods each of which includes the first conductive nanorod, the multi quantum well and the second conductive nanorod, after the step of forming the second conductive nanorods.

13. The method as claimed in claim 12, wherein the transparent insulating material comprises a fluorescent material for converting a portion of light emitted from the nanorods into light with a longer wavelength.

14. The method as claimed in claim 11, wherein the first conductive nanorods, the multi quantum wells and the second conductive nanorods are formed in-situ by means of MO-HVPE, MBE or MOCVD.

15. The method as claimed in claim 11, wherein each of the plurality of (AlₓIn_{y}Ga_{1-x-y})N layers has the amount of In adjusted such that light emitted from the light emitting diode becomes white light as a whole.

16. A light emitting diode, comprising:
a substrate;
a nanorod array including a plurality of nanorods, each of the nanorods including a first conductive nanorod formed perpendicularly to the substrate, a multi quantum well formed by alternately stacking a plurality of (AlₓIn_{y}Ga_{1-x-y})N (where, 0≦x≦1, 0≦y≦1 and 0≦x+y≦1) layers at least two of which have different thicknesses to emit light with at least two peak wavelengths, and a plurality of (AlₓIn_{y}Ga_{1-x-y})N (where, 0≦x≦1, 0≦y<1 and 0≦x+y≦1) barriers on the first conductive nanorod, and a second conductive nanorod formed on the multi quantum well;
an electrode pad connected in common to the first conductive nanorods of the nanorod array for applying a voltage thereto; and
a transparent electrode connected in common to the second conductive nanorods of the nanorod array for applying a voltage thereto.

17. The light emitting diode as claimed in claim 16, wherein each of the first conductive nanorod and the second conductive nanorod is formed of AlₓIn_{y}Ga_{(1-x-y)}N (where, 0≦x≦1, 0≦y<1 and 0≦x+y≦1) or ZnO.

18. The light emitting diode as claimed in claim 16, further comprising a transparent insulating material which fills spaces between the nanorods.

19. The light emitting diode as claimed in claim 18, wherein the transparent insulating material is spin-on-glass (SOG), SiO₂, epoxy or silicone.

20. The light emitting diode as claimed in claim 18, wherein the transparent insulating material fills the spaces between the nanorods to be at a level lower than the height of the nanorods so that tips of the nanorods slightly protrude.

21. The light emitting diode as claimed in claim 20, further comprising a fluorescent material for converting a portion of light emitted from the nanorods into light with a longer wavelength, wherein the fluorescent material is dispersed into the transparent insulating material, and light emitted from the light emitting diode becomes white light as a whole through mixing of the emitted light from the nanorods with the converted light.

22. The light emitting diode as claimed in claim 16, wherein each of the plurality of (AlₓIn_{y}Ga_{1-x-y})N layers has an InGaN layer with a thickness adjusted such that light emitted from the light emitting diode becomes white light as a whole.

23. The light emitting diode as claimed in claim 22, wherein the white light has peak wavelengths within wavelength ranges of at least three colors.

24. The light emitting diode as claimed in claim 16, wherein at least two of the plurality of AlₓIn_{y}Ga_{(1-x-y)}N layers have different amounts of In, and the plurality of AlₓIn_{y}Ga_{(1-x-y)}N layers have thicknesses and amounts of In adjusted such that light emitted from the light emitting diode becomes white light as a whole.

25. A method of fabricating a light emitting diode, comprising the steps of:
forming first conductive nanorods in an array perpendicularly to a substrate;
forming a multi quantum well by alternately stacking a plurality of (AlₓIn_{y}Ga_{1-x-y})N (where, 0≦x<1, 0≦y≦1 and 0≦x+y≦1) layers at least two of which have different thicknesses to emit light with at least two peak wavelengths, and a plurality of (AlₓIn_{y}Ga_{1-x-y})N (where, 0≦x≦1, 0≦y<1 and 0≦x+y≦1) barriers on each of the first conductive nanorods;
forming a second conductive nanorod on each of the multi quantum wells;
forming an electrode pad for applying a voltage to the first conductive nanorods; and
forming a transparent electrode connected in common to the second conductive nanorods for applying a voltage thereto.

26. The method as claimed in claim 25, further comprising the step of filling a transparent insulating material in the spaces between the nanorods each of which includes the first conductive nanorod, the multi quantum well and the second conductive nanorod, after the step of forming the second conductive nanorods.

27. A nanorod, comprising, in a longitudinal direction:
a first conductive nanorod;
a multi quantum well formed by alternately stacking a plurality of (AlₓIn_{y}Ga_{1-x-y})N (where, 0≦x<1, 0≦y≦1 and 0≦x+y≦1) layers and a plurality of (AlₓIn_{y}Ga_{1-x-y})N (where, 0≦x≦1, 0≦y<1 and 0≦x+y≦1) barriers; and
a second conductive nanorod,
wherein at least two of the plurality of (AlₓIn_{y}Ga_{1-x-y})N layers have different amounts of In to emit light with at least two peak wavelengths when a voltage is applied to both ends of the nanorod.

28. The nanorod as claimed in claim 27, wherein the plurality of (AlₓIn_{y}Ga_{1-x-y})N layers include at least three (AlₓIn_{y}Ga_{1-x-y})N layers with different amounts of In, and the nanorod emits white light with the at least three (AlₓIn_{y}Ga_{1-x-y})N layers when a voltage is applied to both ends of the nanorod.
